(19) United States
(12) Patent Application Publication
(10) Pub. No.: US 2005/0056909 A1
(43) Pub. Date: Mar. 17, 2005

(54) Chip diode for surface mounting

(76) Inventor: Hsiao-Ping Chu, Taoyuan Hsien (TW)

Correspondence Address: BACON & THOMAS, PLLC, 625 SLATERS LANE, FOURTH FLOOR, ALEXANDRIA, VA, 22314, US

(21) Appl. No.: 10/661,562

(22) Filed: Sep. 15, 2003

(51) Int. Cl. H01L 29/40

(52) U.S. Cl. 257/528

(57) ABSTRACT

The present invention is to provide a chip diode for surface mounting comprising p+ and n+ type semiconductors on two surfaces of a semiconductor wafer respectively; a plurality of parallel, spaced first and second grooves formed on the p+ type semiconductor along X and Y axes and penetrated through the p+ type semiconductor into the n+ type semiconductor; a plurality of first insulation layers in the first and second grooves adapted to separate and insulate the p+ type semiconductor from the n+ type semiconductor at both sides; a plurality of first conductive metal layers coated on a central portion of the semiconductor wafer for soldering; and a plurality of second conductive metal layers coated on an edge of the semiconductor wafer and extended to sides of the n+ type semiconductor on the second surface of the semiconductor wafer to be in communication therewith.

### FIELD OF THE INVENTION

The present invention relates to diodes and more particularly to a chip diode for surface mounting with improved characteristics.

### BACKGROUND OF THE INVENTION

A commercially available diode is contained in a silicon die having both ends coupled to two conductive metal pieces respectively by soldering. A lead is again coupled to the other end of either conductive metal piece by soldering. Also, the leads are electrically coupled to a circuitry. A manufacturing process of the well known diode comprises the steps of coupling a silicon die and two conductive metal pieces together, etching the silicon die, and encapsulating the silicon die and the conductive metal pieces by an insulated molding by coating therearound. This finishes the manufacturing of the well known diode.

In the manufacturing process of the well known diode, an epoxy or any of other plastic materials is used as the insulated molding for encapsulating the etched silicon die. However, heat resistant capability of epoxy or the plastic material is low. As such, the diode, formed by molding the epoxy or the plastic material therearound, as a rectification element for large current, high power input is susceptible to damage in a high temperature environment. As such, an electronic device having such rectification elements may not operate normally. This in turn may lower quality and shorten a useful life of the electronic device as well as cause difficulties in maintenance. Moreover, a relatively large space is occupied by the molding formed by the epoxy or the plastic material. As a result, the goal of reducing the size of well known diode is not achieved. Hence, a need for improvement exists.

### SUMMARY OF THE INVENTION

One object of the present invention is to provide a chip diode for surface mounting comprising p+ and n+ type semiconductors having a predetermined depth formed on first and second surfaces of a semiconductor wafer respectively by diffusion; a plurality of diodes formed on each of the first and the second surfaces of the semiconductor wafer by performing a number of semiconductor manufacturing techniques such as photolithography, etching, implanting, and sintering; a plurality of parallel, spaced first grooves and second grooves formed on the p+ type semiconductor along X and Y axes respectively by etching, each of the first grooves and the second grooves being penetrated through the p+ type semiconductor into the n+ type semiconductor; a plurality of first insulation layers in the first and the second grooves formed by sintering, the first insulation layers being adapted to separate and insulate the p+ type semiconductor from the n+ type semiconductor at both sides; a plurality of first conductive metal layers coated on a central portion of the semiconductor wafer as a first conductive terminal for soldering; and a plurality of second conductive metal layers coated on an edge of the semiconductor wafer and extended to sides of the n+ type semiconductor on the second surface of the semiconductor wafer to be in communication therewith as a second conductive terminal for soldering. By utilizing the present invention, the above drawbacks of the prior art can be overcome.

In one aspect of the present invention, two separate conductive terminals are formed on top of each diode. The conductive terminals are electrically coupled to the p+ type semiconductor and the n+ type semiconductor of each diode respectively. As an end, thus produced chip diodes having characteristics of devices for surface mounting can be mounted on a circuit.

In another aspect of the present invention, the chip diodes for surface mounting are produced without involving any subsequent encapsulation step. As such, thus produced chip diodes have advantages of great improvement of heat transfer capability of diode for withstanding a relatively high operating temperature, simple construction and manufacturing process, great reduction of diode size, and significant reduction of manufacturing cost.

The above and other objects, features and advantages of the present invention will become apparent from the following detailed description taken with the accompanying drawings.

### BRIEF DESCRIPTION OF THE DRAWINGS

FIG. 1 is a cross-sectional view of a preferred embodiment according to the invention, where a p+ type semiconductor is formed on the top of an n type semiconductor by diffusion;

FIG. 2 is a view similar to FIG. 1, where an n+ type semiconductor is formed on the bottom of the n type semiconductor by diffusion;

FIG. 3a is a cross-sectional view taken along X axis showing a plurality of first grooves and a trough formed on top and bottom respectively by photolithography and etching;

FIG. 3b is a cross-sectional view taken along Y axis showing a plurality of second grooves and a plurality of troughs formed on top and bottom respectively by photolithography and etching;

FIG. 4a is a cross-sectional view taken along X axis showing two chip diodes to be produced on the semiconductor wafer;

FIG. 4b is a cross-sectional view taken along Y axis showing two chip diodes to be produced on the semiconductor wafer;

FIG. 5a is a cross-sectional view taken along X axis showing first insulation layers to be formed by filling glass plasma into the grooves and sintering the same;

FIG. 5b is a cross-sectional view taken along Y axis showing first insulation layers to be formed by filling glass plasma into the grooves and sintering the same;

FIG. 6a is a cross-sectional view taken along X axis showing first metal layers to be formed by filling metal paste into the troughs and sintering the same;

FIG. 6b is a cross-sectional view taken along Y axis showing first metal layers to be formed by filling metal paste into the troughs and sintering the same;

FIG. 7a is a cross-sectional view taken along X axis showing second insulation layers to be formed by filling glass plasma into the first metal layers and sintering the same;

FIG. 7b is a cross-sectional view taken along Y axis showing second insulation layers to be formed by filling glass plasma into the first metal layers and sintering the same;

FIG. 8 is a cross-sectional view taken along X axis showing a plurality of trenches to be formed on top of the semiconductor wafer in the Y axis by photolithography and etching;

FIG. 9 is a cross-sectional view taken along X axis showing second metal layers to be formed by filling metal paste into the trenches and sintering the same;

FIG. 10a is a cross-sectional view taken along X axis showing third metal layers to be formed on both the p+ type semiconductor and the second metal layers of the semiconductor wafer by plating;

FIG. 10b is a cross-sectional view taken along Y axis showing third metal layers to be formed on both the p+ type semiconductor and the second metal layers of the semiconductor wafer by plating; FIG. 11a is a cross-sectional view taken along X axis showing chip diodes to be formed on the wafer by cutting;

FIG. 11b is a cross-sectional view taken along Y axis showing chip diodes to be formed on the wafer by cutting; and

FIG. 12 is partially cut-away perspective view of the produced chip diode.

### DETAILED DESCRIPTION OF THE PREFERRED EMBODIMENTS

The invention is directed to a chip diode for surface mounting in which p+ type semiconductor and n+ type semiconductor having predetermined depths are formed on top and bottom of a semiconductor wafer respectively by diffusion. Next, a plurality of diodes are formed on the semiconductor wafer by performing a number of semiconductor manufacturing techniques such as photolithography, etching, implanting, and sintering. Also, an insulation layer can be formed on the semiconductor at top or bottom of the diode for dividing the semiconductor into two separated and insulated portions. Further, a conductive metal layer is coated on a central portion of the semiconductor as a conductive terminal for soldering and another conductive metal layer is coated on a top edge thereof as another conductive terminal for soldering. As such, two conductive terminals in communication with the semiconductors are formed at two opposite surfaces of the semiconductor respectively. As an end, the formed diodes can be used for surface mounting (SMD).

In a process of manufacturing a chip diode of the invention, a plurality of trenches are formed on top and bottom of the semiconductor wafer along X and Y axes respectively by etching. Also, insulation layers are formed by sintering. As such, constructions formed along X and Y axes (i.e., viewed from X-X and Y-Y sections) of the semiconductor wafer are not the same in respective steps of manufacturing the chip diode. Thus, the following detailed description of a preferred embodiment of the invention will focus on constructions of the semiconductor wafer viewed from X-X and Y-Y sections respectively in respective manufacturing step, thereby fully describing differences of the chip diode in X and Y axes.

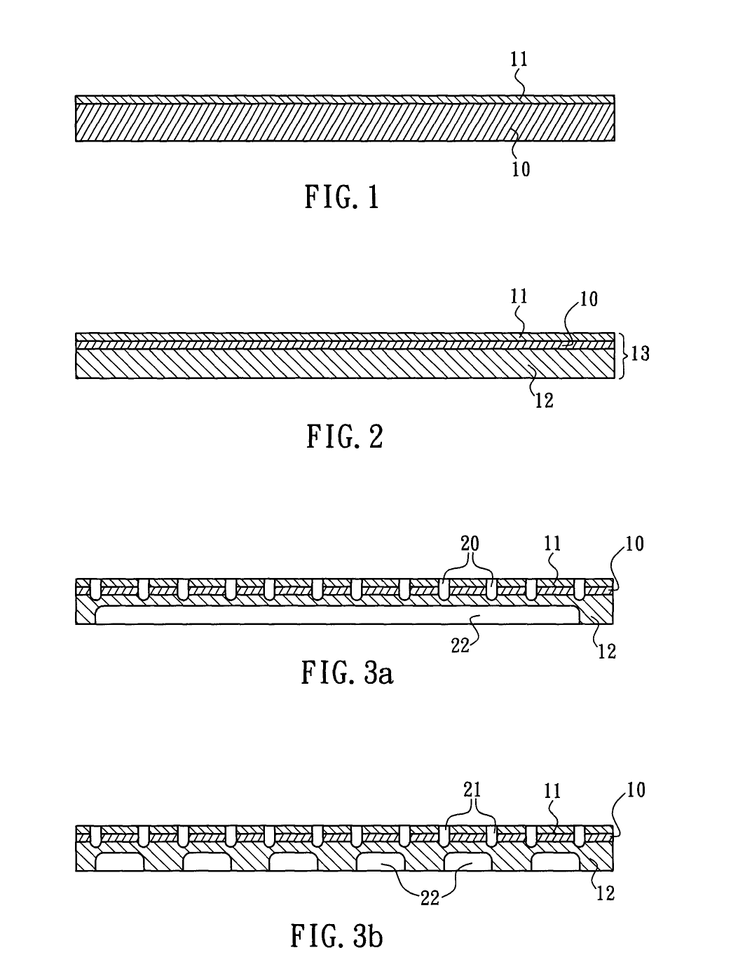

Referring to FIG. 1, there is shown a preferred embodiment of the invention in which a p+ type semiconductor 11 having a predetermined depth is formed on top of an n type semiconductor 10 by diffusing boron ions thereinto. Next, as shown in FIG. 2, an n+ type semiconductor 12 having a predetermined depth is formed on bottom of the n type semiconductor 10 by diffusing boron ions thereinto. This produces a semiconductor wafer 13 to be used in subsequent manufacturing steps of the invention. The p+ type semiconductor 11 and the n+ type semiconductor 12 having predetermined depths are formed on top and bottom of the n type semiconductor 10 respectively by an ion diffusion technique in the embodiment, while it is appreciated by those skilled in the art that the above ion diffusion technique may be replaced by another suitable technique (e.g., any of other diffusion techniques or implantation) without departing from the scope and spirit of the invention in which an n+ type semiconductor 12 and a p+ type semiconductor 11 (or a p+ type semiconductor 11 and an n+ type semiconductor 12) having predetermined depths are formed on top and bottom (or bottom and top) of a p type or n type semiconductor 10 of the invention respectively. It is contemplated that thus type semiconductor 10 are also within the scope of the invention.

Next, in the embodiment a plurality of parallel first grooves 20 and second grooves 21 are formed on top of the semiconductor wafer 13 along X and Y axes respectively depending on required sizes by photolithography and etching. This is best illustrated in the cross-sectional views taken along X and Y axes of FIGS. 3a and 3b respectively. As shown, each of the first groove 20 and the second groove 21 penetrates through the p+ type semiconductor 11 a plurality of spaced, parallel troughs 22 are formed on bottom of the semiconductor wafer 13 (i.e., on bottom of the n+ type semiconductor 12) along X axis depending on required sizes by photolithography and etching. This is again best illustrated in FIGS. 3a and 3b in which a bottom of each trough 22 is spaced from that of each of the first groove 20 and the second groove 21 by a predetermined distance. Also, a width of each trough 22 along X axis direction is approximately equal to a distance between two adjacent second grooves 21.

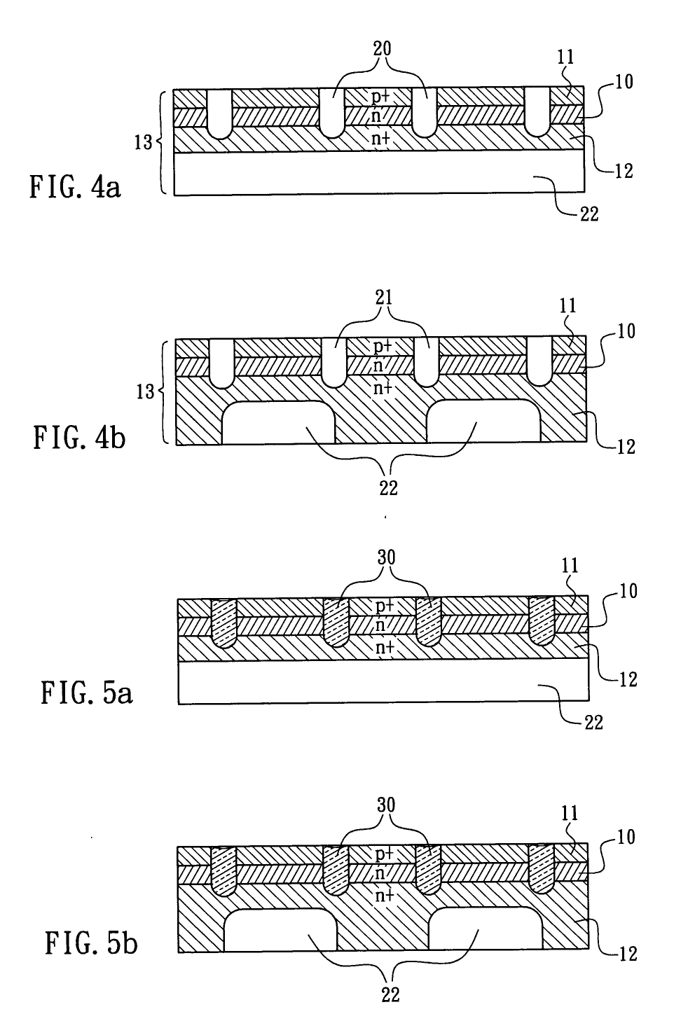

For the purpose of fully describing differences of the chip diode in X and Y axes in the manufacturing process of the invention, sections of the chip diode are taken along X and Y axes (see FIGS. 4a and 4b). As shown, four parallel first grooves 20 and four parallel second grooves 21 are formed on top of the semiconductor wafer 13 along Y and X axes respectively. Also, two parallel troughs 22 are formed on bottom of the semiconductor wafer 13 along X axis only.

Next, in the embodiment glass plasma is prepared by uniformly mixing glass powder with liquid adhesive prior to filling into the grooves 20 and 21. This is best illustrated in the cross-sectional views taken along X and Y axes of FIGS. 5a and 5b respectively. The filled glass plasma is further sintered to form first insulation layers 30 in the grooves 20 and 21. The first insulation layer 30 in the first groove 20 or the second groove 21 is adapted to separate and insulate the p+ type semiconductor 11 from the n type semiconductor 10 at both sides.

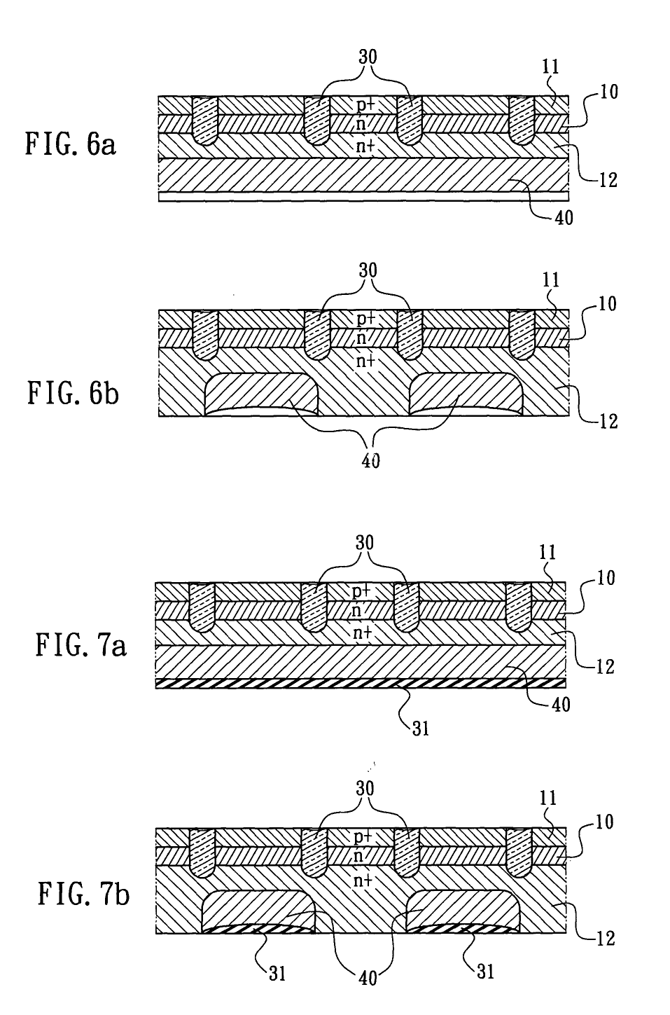

Next, in the embodiment metal paste (e.g., copper paste, silver paste, gold paste, etc.) is filled into the troughs 22. This is best illustrated in the cross-sectional views taken along X and Y axes of FIGS. 6a and 6b respectively. The filled metal paste is further sintered to form first metal layers 40 in the troughs 22. Next, in the embodiment fill the glass plasma, prepared by uniformly mixing glass powder with liquid adhesive, into the troughs 22 prior to coating on the first metal layers 40. This is best illustrated in the cross-sectional views taken along X and Y axes of FIGS. 7a and 7b respectively. Alternatively, coat the glass plasma on bottom of the semiconductor wafer 13 prior to sintering to form a second insulation layer 31 on bottom of the semiconductor wafer 13.

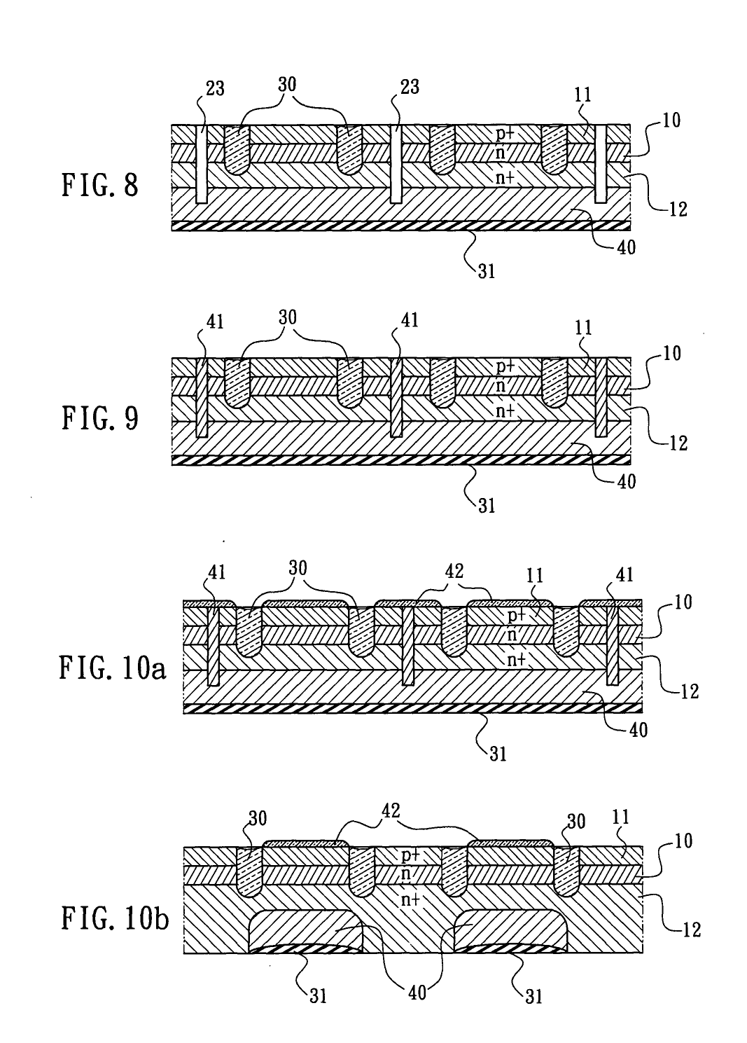

Next, in the embodiment as shown in the cross-sectional view taken along X axis of FIG. 8, one of a plurality of trenches 23 is formed on top of the semiconductor wafer 13 in the Y axis between two adjacent ones of two pairs of first insulation layers 30 by photolithography and etching. As shown, the trench 23 is recessed into the first metal layer 40. As such, metal paste (e.g., copper paste, silver paste, gold paste, etc.) can be filled into the trenches 23 having a predetermined depth prior to sintering. This is best illustrated in the cross-sectional view taken along X axis of FIG. 9. A plurality of second metal layers 41 are thus formed in the trenches 23 and are in communication with the first metal layer 40.

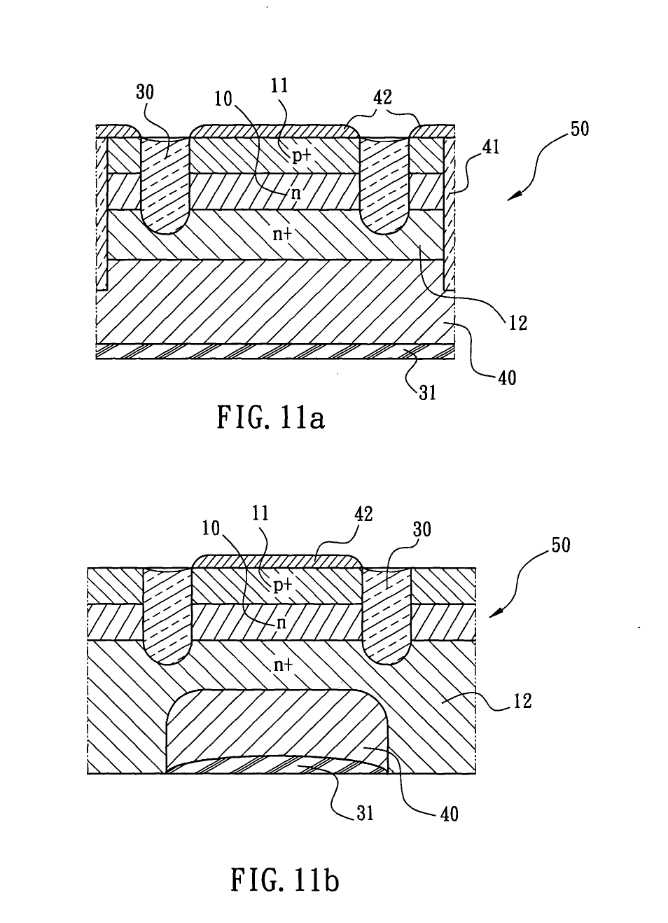

Next, in the embodiment as shown in the cross-sectional views taken along X and Y axes of FIGS. 10a and 10b, at least one layer of conductive metal (e.g., nickel and/or gold) is plated on top of the semiconductor wafer 13 (i.e., on top of the p+ type semiconductor 11 and the second metal layers 41) to form third metal layers 42 by chemically plating. Finally, as shown in the cross-sectional views taken along X and Y axes of FIGS. 11a and 11b, cut the n type semiconductor 10 along X and Y axes between two adjacent first metal layers 40 corresponding to the trench 23 for forming a plurality of chip diodes 50.

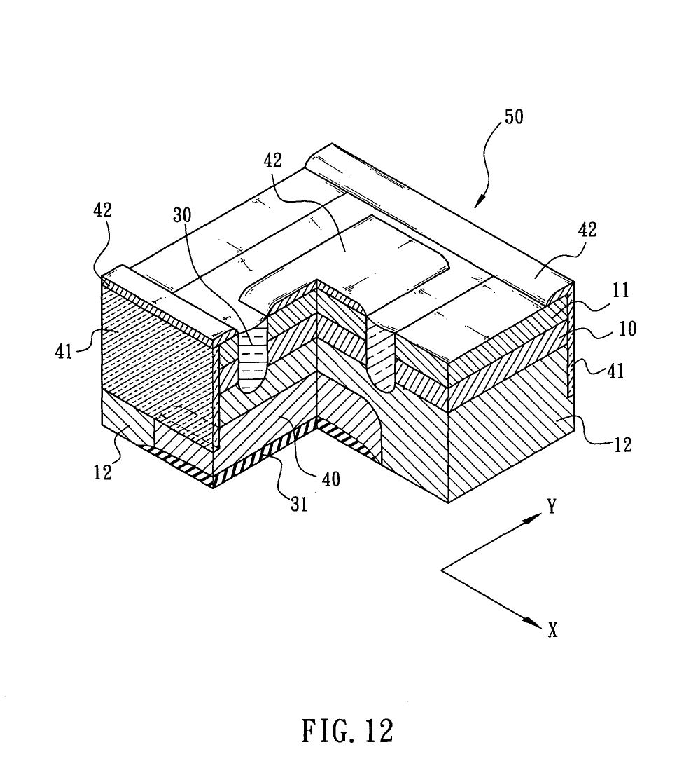

Referring to FIG. 12, in the embodiment each of the first insulation layers 30 on the chip diode 50 in the first groove 20 or the second groove 21 is adapted to separate and insulate the p+ type semiconductor 11 from the n type semiconductor 10 at both sides. Thus, we can view that a conductive terminal is formed on a central portion of the p+ type semiconductor 11 for soldering after plating the third metal layers 42 on the p+ type semiconductor 11 at a central portion of top of the chip diode 50. For the p+ type semiconductor 11 on top edge of the chip diode 50, the p+ type semiconductor 11 with the third metal layer 42 formed thereon by plating can communicate with the n+ type semiconductor 12 on bottom of the chip diode 50 via the second metal layer 41 and the first metal layer 40 sequentially. Note that in the embodiment the second metal layers 41 are formed at sides of the p+ type semiconductor 11 and the n type semiconductor 10 of the chip diode 50 by sintering. Also, one end of each second metal layer 41 is in communication with the third metal layer 42 on a top edge of the chip diode 50 and the other end thereof is in communication with both the n type semiconductor 10 and the first metal layer 40 on bottom of the chip diode 50 respectively. As such, the second metal layer 41 is adapted to short-circuit the p+ type semiconductor 11, the n type semiconductor 10, and the n+ type semiconductor 12 at sides of the diode 50 to form an n+ type semiconductor 12 of the second metal layer 41. Thus, we can view that another conductive terminal is formed on the n+ type semiconductor 12 of the diode 50 for soldering after plating the third metal layers 42 on the p+ type semiconductor 11 at a top edge of the chip diode 50. In such a manner, two separate conductive terminals for soldering are formed on top of the chip diode 50 without involving any subsequent encapsulation step. The conductive terminals are electrically coupled to the p+ type semiconductor 11 and the n+ type semiconductor 12 of each diode respectively. As an end, the conductive terminals are used as conductive terminals for soldering when a surface mounting (SMD) is performed.

As stated above, referring to FIG. 12 again, the chip diodes 50 of the invention can be manufactured in mass production since its construction and manufacturing process are simple and without involving any subsequent encapsulation step. Further, the chip diodes 50 are readily for surface mounting, thereby greatly increasing production speed and lowering manufacturing cost. Furthermore, heat transfer capability is greatly improved and diodes' useful life is prolonged because no insulated molding is formed on the chip diode 50. It is further noted that in the disclosed embodiment the chip diodes of the invention are formed without involvement of any subsequent encapsulation step, while it is appreciated by those skilled in the art that such illustrated manufacturing process may be replaced by another suitable one in other embodiments without departing from the scope and spirit of the invention. For example, one of ordinary skill in the art may encapsulate the exposed p+ type semiconductor 11, n type semiconductor 10, and n+ type semiconductor 12 of the chip diode 50 for protection (i.e., prevent it from being oxidized or damaging) by employing other encapsulation techniques and materials. It is contemplated that thus formed chip diodes are also within the scope of the invention.

While the invention has been described by means of specific embodiments, numerous modifications and variations could be made thereto by those skilled in the art without departing from the scope and spirit of the invention set forth in the claims.

1. A chip diode for surface mounting, comprising:
a first type semiconductor having a predetermined depth formed on a first surface of a semiconductor wafer by diffusion;
a second type semiconductor having a predetermined depth formed on a second surface of a semiconductor wafer by diffusion wherein the second type semiconductor is different from the first type semiconductor and the second surface is opposite the first surface;
a plurality of diodes formed on each of the first and the second surfaces of the semiconductor wafer;
a plurality of first insulation layers formed on the diodes at the first surface of the semiconductor wafer for dividing the semiconductor wafer into two separated and insulated portions;
a plurality of first conductive metal layers coated on a central portion of the semiconductor wafer as a first conductive terminal for soldering; and
a plurality of second conductive metal layers coated on an edge of the semiconductor wafer and extended to sides of the second type semiconductor on the second surface of the semiconductor wafer to be in communication therewith as a second conductive terminal for soldering.

2. The chip diode of claim 1, wherein each of the first and the second conductive metal layers is formed by chemically plating at least one layer of conductive metal on a first surface of the diodes corresponding to a central portion of the semiconductor wafer.

3. The chip diode of claim 2, further comprising:
a plurality of parallel, spaced first grooves and second grooves formed on the first type semiconductor at the first surface of the diodes along X and Y axes respectively by etching, each of the first grooves and the second grooves being penetrated through the first type semiconductor into the second type semiconductor; and
a plurality of first insulation layers in the first and the second grooves formed by sintering, the first insulation layers being adapted to separate and insulate the first type semiconductor from the second type semiconductor at both sides.

4. The chip diode of claim 3, wherein the first insulation layers are glass insulation layers formed by sintering glass plasma.

5. The chip diode of claim 3, further comprising at least one trough formed on the second surface type semiconductor at a second surface of the diodes along X axis by etching wherein a bottom of each trough is spaced from that of each of the first grooves and the second grooves by a predetermined distance and a width of each trough along X axis direction is approximately equal to a distance between two adjacent second grooves.

6. The chip diode of claim 5, wherein each of the second conductive metal layers comprises:
a first conductive metal stratum sintered in the troughs;
a second conductive metal stratum sintered in at least one side of the diodes and extended in sides of the first and the second type semiconductors to be in communication with the first conductive metal stratum; and
a third conductive metal stratum formed by chemically plating at least one layer of conductive metal on the first surface of the diodes corresponding to edges of the first and the second type semiconductors and the second conductive metal stratum.

7. The chip diode of claim 6, further comprising a plurality of second insulation layers formed on the first conductive metal stratum by sintering.

8. The chip diode of claim 7, wherein the second insulation layers are glass insulation layers formed by sintering glass plasma.
